(19) United States
(12) Patent Application Publication
(10) Pub. No.: US 2012/0104502 A1
(43) Pub. Date: May 3, 2012

(54) METHOD OF PRODUCING SEMICONDUCTOR DEVICE, AND SEMICONDUCTOR DEVICE

(75) Inventors: Toru Imori, Ibaraki (JP); Junichi Ito, Ibaraki (JP); Hajime Momoi, Saitama (JP); Tomohiro Shibata, Tokyo (JP); Shuji Ikeda, Tokyo (JP)

(73) Assignee: JX NIPPON MINING & METALS CORPORATION, Tokyo (JP)

(21) Appl. No.: 13/260,948

(22) PCT Filed: Mar. 24, 2010
(86) PCT No.: PCT/JP2010/055042

§ 371 Date: Jan. 4, 2012

(30) Foreign Application Priority Data
Mar. 31, 2009 (JP) 2009-086020

(51) Int. Cl. H01L 29/78; H01L 21/336

(52) U.S. Cl. 257/368; 438/294; 257/E29.255; 257/E21.409

(57) ABSTRACT

Disclosed is a method of producing a semiconductor device, able to form a source/drain of a Schottky junction (FET) with simple steps and able to improve the device characteristics. A gate is formed on an element region defined in a silicon substrate layer by element isolation regions (first step), the silicon substrate is etched by self-alignment using the gate and the element isolation regions as masks (second step), and an insulating film is formed on the side surfaces of the gate (third step). Then, a metal film acting as the source/drain is selectively formed on the etching region of the silicon substrate by electroless plating (fourth step).

### TECHNICAL FIELD

The present invention relates to a method for manufacturing a semiconductor device and to the semiconductor device, and particularly, relates to a method for manufacturing a field-effect transistor that uses Schottky junction for source/drain.

### Background Art

Heretofore, a semiconductor device (integrated circuit) has been known, in which large numbers of circuit elements (for example, transistors) and wires are built on one substrate. As a semiconductor element that composes this semiconductor device, for example, a field-effect transistor (FET) has been known, which includes: source/drain which make a pair and are formed apart from each other by a channel region in an element region defined in a surface layer of a silicon substrate; and a gate in which a polysilicon layer is formed on the channel region while interposing a gate insulating film therebetween.

In the field of the semiconductor device, microfabrication of the semiconductor element has been required in order to realize speed enhancement/integration enhancement, and for example, the microfabrication has been achieved by shortening a gate length of the FET and further thinning the gate insulating film.

Moreover, there has been proposed a technology of composing the source/drain of the FET not by a diffusion layer but by metal, the diffusion layer being formed by doping impurities into the silicon substrate (for example, Non-Patent Document 1). In accordance with such a technology, in comparison with the case of composing the source/drain by the diffusion layer, it is easy to form a shallow junction, and in addition, it becomes possible to obtain overwhelmingly low resistance.

The FET, in which the source/drain are realized by the Schottky junction by the metal/silicon substrate, is called a Schottky junction FET.

A description is made below of a typical example of a method for manufacturing the Schottky junction FET, which has been used heretofore, with reference to the drawings.

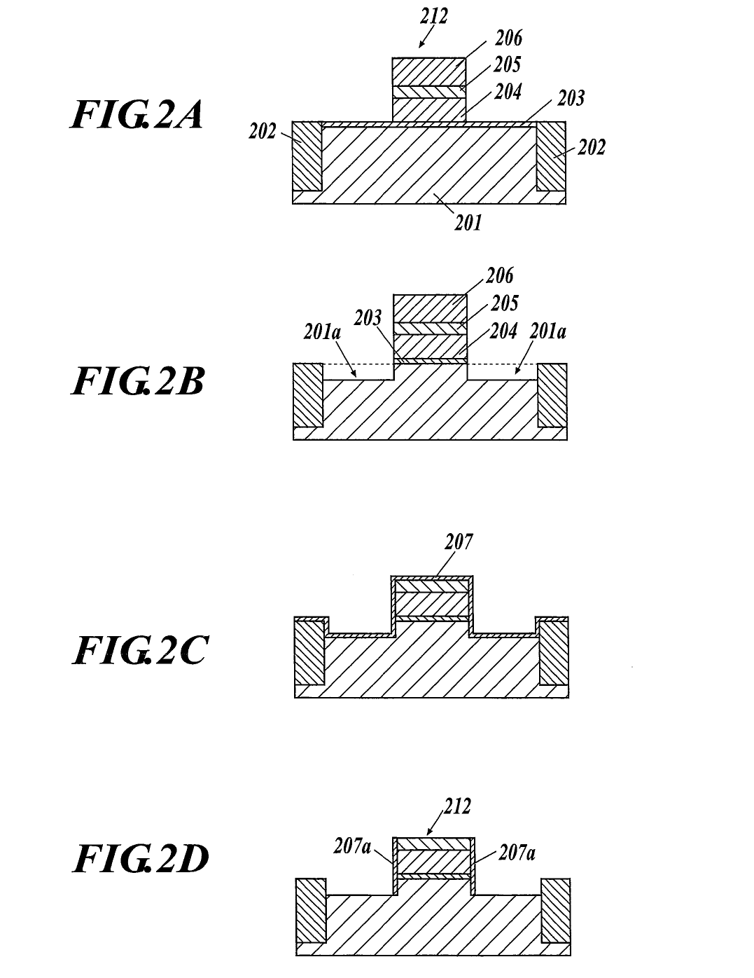

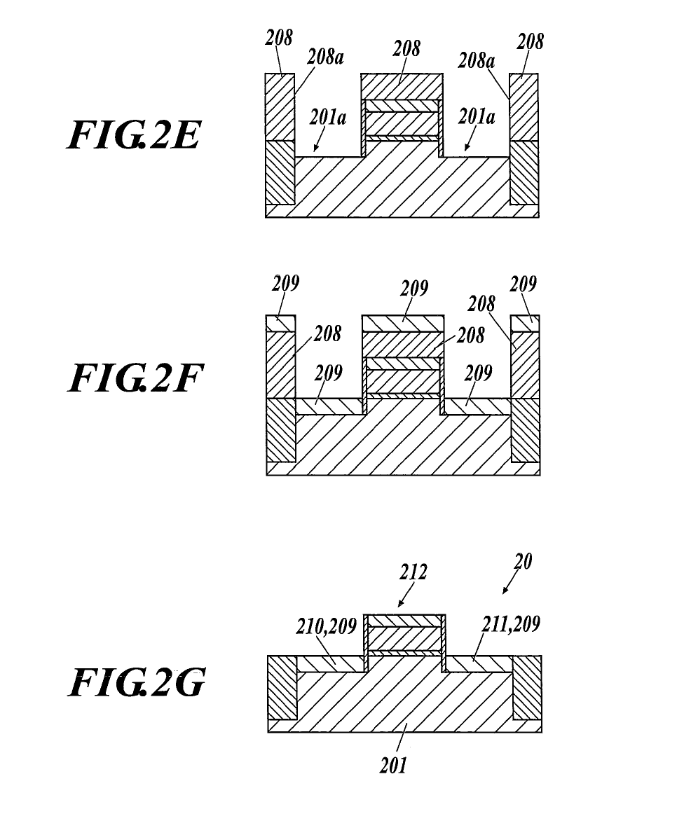

FIG. 2 is explanatory views showing an example of a conventional manufacturing process of the Schottky junction FET.

FIG. 2 shows formation of source/drain after a gate 212 is formed on a silicon substrate 201. That is to say, at a preliminary stage shown in FIG. 2A, the gate 212 of the Schottky junction FET 20 is formed on the silicon substrate 101 by a general manufacturing process of the semiconductor device.

Note that the gate 212 is composed of: a gate insulating film 203; a gate electrode 204; and an insulating film 205 that covers the gate electrode. Here, the gate electrode 204 is an electrode, which is formed of metal or a compound having metallic conductivity (for example, Ni, Co, Pt or an alloy of these), and plays a role of a so-called gate for controlling movement of electrodes.

FIG. 2A shows a state where, after the gate insulating film 203, the gate electrode 204 and the insulating film 205 are formed on the entire surface of the silicon substrate 201, unnecessary portions of the gate electrode 204 and the insulating film 205 are removed by a photo etching step by using a resist pattern 206 as a mask.

After the gate electrode 204 and the insulating film 205 are removed as shown in FIG. 2A, the gate insulating film 203 is further removed. Then, the silicon substrate 201 is etched by a predetermined depth by self-alignment (FIG. 2B). On such etching regions 201a, the source/drain are formed.

Subsequently, after the resist pattern 206 is peeled off, for example, a silicon nitride film 207 is formed on the entire surface of the substrate (FIG. 2C). Then, etching back by anisotropic etching is performed for this silicon nitride film 207, whereby sidewalls 207a are formed on side surfaces of the gate 212 (FIG. 2D).

After the sidewalls 207a are formed, a resist pattern 208, in which opening portions 208a are provided so as to expose the etching regions 201a of the silicon substrate 201, is formed by a photolithography step (FIG. 2E). A metal film (for example, of Ni) is formed on the entire surface by physical vapor deposition (PVD) such as sputtering (FIG. 2F), and the resist pattern 208 is peeled off (FIG. 2G).

By the above-described steps, the Schottky junction FET 20 is obtained. Metal films 209 formed on both sides of the gate 212 become source/drain 210 and 211, and form the Schottky junction with the silicon substrate 201.

### Prior Art Document

Non-Patent Document

Non-Patent Document 1: “Dopant-Segregation Schottky Barrier Transistors”, by KINOSHITA Atsuhiro, and two others, Toshiba Review, Vol. 59, No. 12 (2004)

### Disclosure of the Invention

### Problem to be Solved by the Invention

However, in the above-mentioned conventional method for manufacturing the Schottky junction FET, complicated steps such as the photolithography step become necessary in order to form the source/drain 210 and 211 on the etching regions 201a of the silicon substrate 201. Therefore, disadvantage is brought about for achieving enhancement of yield of the semiconductor device and price reduction thereof.

Moreover, the metal films 209 are evaporated on the etching regions 201a of the silicon substrate 201 by the PVD, and accordingly, irregularities are prone to be formed on interfaces between the silicon substrate 201 and the metal films 209, and there is an apprehension that a decrease of device characteristics may be brought about.

It is an object of the present invention to provide a method for manufacturing a semiconductor device, which is capable of forming the source/drain of the Schottky junction FET by a simple process, and is capable of enhancing the device characteristics.

### Means for Solving the Problems

In order to achieve the foregoing object, an invention according to claim 1 is a method for manufacturing a semiconductor device, including:

a first step of forming a gate on an element region defined in a surface layer of a silicon substrate by an element isolation region;

a second step of etching the silicon substrate by self-alignment by using the gate and the element isolation region as masks;

a third step of forming an insulating film on a side surface of the gate; and

a fourth step of selectively forming a metal film which is to be a source/drain, on an etching region of the silicon substrate by an electroless plating method.

An invention according to claim 2 is the method for manufacturing the semiconductor device according to claim 1, wherein the metal film is made of one type of metal selected from a group of gold, platinum, silver, copper, palladium, nickel, cobalt and ruthenium, or an alloy obtained by combining two types or more of the metal selected from the group with one another, or an alloy containing at least one type of the metal selected from the group.

An invention according to claim 3 is a semiconductor device including:

a gate formed on an element region defined in a surface layer of a silicon substrate by an element isolation region; and

a source/drain formed on an etching region of the silicon substrate etched by using the gate and the element isolation region as masks, wherein

the source/drain has a metal film selectively formed by an electroless plating method.

An invention according to claim 4 is the semiconductor device according to claim 3, wherein the metal film is made of one type of metal selected from a group of gold, platinum, silver, copper, palladium, nickel, cobalt and ruthenium, or an alloy obtained by combining two types or more of the metal selected from the group with one another, or an alloy containing at least one type of the metal selected from the group.

### Advantageous Effects of the Invention

In accordance with the present invention, the forming process of the source/drain of the Schottky junction FET is simplified, and accordingly, the enhancement of the yield of the semiconductor device and the price reduction thereof can be achieved. Specifically, the conventional photolithography step can be omitted.

Moreover, the metal films which become the source/drain are formed not by the PVD but by the electroless plating method, and accordingly, the interfaces thereof with the silicon substrate become smooth, and the enhancement of the device characteristics can be expected.

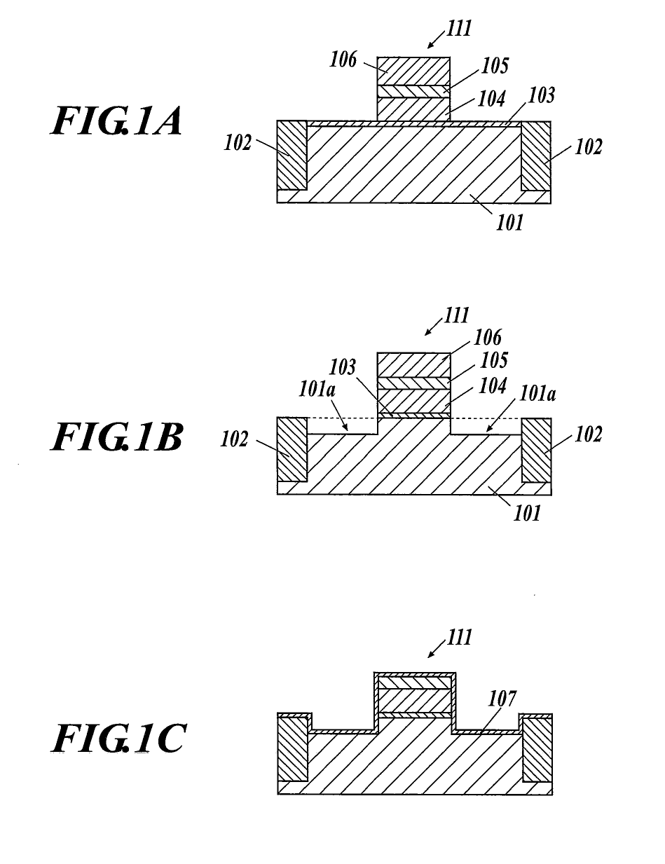

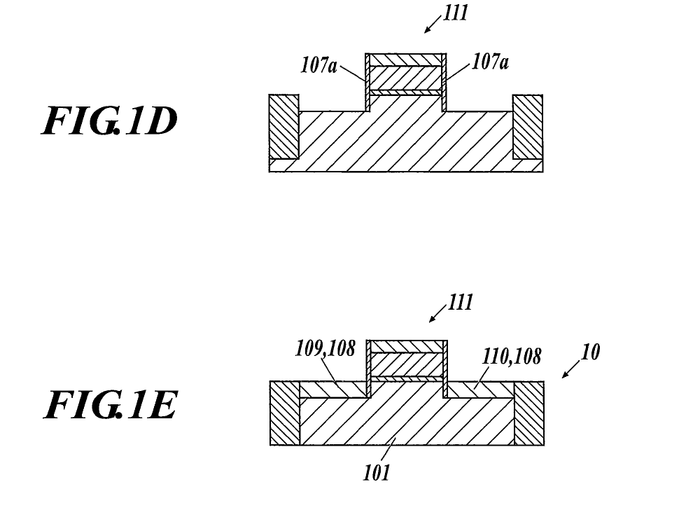

### BRIEF DESCRIPTION OF THE DRAWINGS

[FIG. 1A] This is an explanatory view showing an example of a manufacturing process of a Schottky junction FET according to this embodiment.

[FIG. 1B] This is an explanatory view showing the example of the manufacturing process of the Schottky junction FET according to this embodiment.

[FIG. 1C] This is an explanatory view showing the example of the manufacturing process of the Schottky junction FET according to this embodiment.

[FIG. 1D] This is an explanatory view showing the example of the manufacturing process of the Schottky junction FET according to this embodiment.

[FIG. 1E] This is an explanatory view showing the example of the manufacturing process of the Schottky junction FET according to this embodiment.

[FIG. 2A] This is an explanatory view showing an example of a conventional manufacturing process of a Schottky junction FET.

[FIG. 2B] This is an explanatory view showing the example of the conventional manufacturing process of the Schottky junction FET.

[FIG. 2C] This is an explanatory view showing the example of the conventional manufacturing process of the Schottky junction FET.

[FIG. 2D] This is an explanatory view showing the example of the conventional manufacturing process of the Schottky junction FET.

[FIG. 2E] This is an explanatory view showing the example of the conventional manufacturing process of the Schottky junction FET.

[FIG. 2F] This is an explanatory view showing the example of the conventional manufacturing process of the Schottky junction FET.

[FIG. 2G] This is an explanatory view showing the example of the conventional manufacturing process of the Schottky junction FET.

### BEST MODE FOR CARRYING OUT THE INVENTION

A description is made below in detail of an embodiment of the present invention with reference to the drawings.

FIG. 1 is explanatory views showing an example of a manufacturing process of a Schottky junction FET according to this embodiment.

FIG. 1 shows formation of source/drain after a gate 111 is formed on a silicon substrate 101.

That is to say, at a preliminary stage shown in FIG. 1A, the gate 111 of the Schottky junction FET 10 is formed on the silicon substrate 101 by a general manufacturing process of a semiconductor device.

In a brief description, in a predetermined region of the p-type silicon substrate 101, there is formed an element isolation region 102 composed of a silicon oxide film with a depth of 300 to 400 nm. An element region is defined by this element isolation region 102.

On the entire surface of the substrate, a gate insulating film (oxide film) 103 with a thickness of 5 nm is formed, and on the gate insulating film 103, a gate electrode 104 and an insulating film 105 are formed, the gate electrode 104 being composed of polycrystalline silicon, a metal film or a silicide film, each of which having a thickness of 100 to 150 nm. Then, by a photo etching step by using a resist pattern 106 as a mask, the gate electrode 104 and the insulating film 105 are removed while leaving a portion that becomes the gate.

By the above-described process, a state shown in FIG. 1A is obtained.

After the gate electrode 104 and the insulating film 105 are removed as shown in FIG. 1A, the gate insulating film 103 is further removed. Then, the silicon substrate 101 is etched by a predetermined depth (for example, 10 to 100 nm) by self-alignment (FIG. 1B). On such etching regions 101a, the source/drain are formed.

Here, the etching by the self-alignment refers to performing an etching process without using a photomask but by using the existing pattern (as a mask). In this embodiment, source/drain regions are etched by using, as masks, the gate 111 and the isolation oxide film (element isolation region) 102, and accordingly, the etching by the self-alignment is performed.

Subsequently, after the resist pattern 106 is peeled off, a silicon nitride film 107 with a thickness of 10 nm or less is formed (FIG. 1C). Then, etching back by anisotropic etching is performed for this silicon nitride film 107, whereby sidewalls 107a are formed on side surfaces of the gate 111 (FIG. 1D).

Note that the process up to here is the same as that in the conventional example (refer to FIG. 2).

After the sidewalls 107a are formed, metal films (for example, of Ni) 108 with a thickness of 10 to 100 μm are selectively formed in the etching regions 101a by an electroless plating method (FIG. 1E). When the electroless plating method is used, metal is formed on silicon by an autocatalytic reaction of the silicon. Hence, the metal films 108 are formed only on the etching regions 101a of the silicon substrate 101.

Specifically, an electroless nickel plating solution, which contains 0.08 M of nickel sulfate, 0.10 M of citric acid and 0.20 M of phosphinic acid as main components, is adjusted so that pH thereof can be equal to 9.5 (pH=9.5). Then, such a semiconductor device 10 is immersed into this electroless nickel plating solution at 70° C. for two minutes. In such a way, the nickel films (metal films) 108 with a thickness of approximately 50 nm are formed.

Note that, though the case is illustrated where nickel is used as an example of a material of the metal films to be formed by the electroless plating method, for example, there can be used a type of metal selected from the group of gold, platinum, silver, copper, palladium, cobalt and ruthenium, an alloy obtained by combining two types or more thereof with one another, or an alloy containing at least one type thereof . In the case of these metals, the metal films can be easily formed by the electroless plating method, and in addition, the metals are suitable as materials of the source/drain.

By the above-described process, the Schottky junction FET 10 is obtained. The metal films 108 formed on both sides of the gate 111 become source/drain 109 and 110, and form Schottky junctions with the silicon substrate 101.

As mentioned above, in this embodiment, the gate (111) is formed in the element region defined on the surface layer of the silicon substrate (101) by the element isolation region (102) (first step, FIG. 1A), and by using the gate (111) and the element isolation region (102) as masks, the silicon substrate (101) is etched by the self-alignment (second step, FIG. 1B).

Subsequently, the insulating films (silicon nitride film 107, sidewalls 107a) are formed on the side surfaces of the gate (111) (third step, FIGS. 1C and 1D), and the metal films 108 which become the source/drain (109, 110) are selectively formed on the etching regions (101a) of the silicon substrate (101) by the electroless plating method (fourth step, FIG. 1E).

In such a way, the process of forming the source/drain of the Schottky junction FET is simplified, and accordingly, enhancement of yield of the semiconductor device and price reduction thereof can be achieved. Specifically, the conventional photolithography step can be omitted.

Moreover, the metal films which become the source/drain are formed not by PVD but by the electroless plating method, and accordingly, interfaces thereof with the silicon substrate become smooth, and enhancement of device characteristics can be expected.

The metal films (108) formed in the fourth step are composed of a type of metal selected from the group of gold, platinum, silver, copper palladium, nickel, cobalt and ruthenium, an alloy obtained by combining two types or more thereof with one another, or an alloy containing at least one type thereof. In such a way, the source/drain can be easily formed by the electroless plating method.

The description has been specifically made above of the inventions, which have been made by the inventor of the present invention, based on the embodiment; however, the present invention is not limited to the above-described embodiment, and is modifiable within the scope without departing from the spirit thereof.

In the above-described embodiment, the description has been made of the case of forming the Schottky junction FET on the silicon substrate; the present invention is also applicable to the case of forming the Schottky junction FET on an SOI (silicon-on-insulator) substrate.

It should be considered that the embodiment disclosed this time is illustrative and non-restrictive in all aspects. The scope of the present invention is defined not by the foregoing description but by the scope of claims, and is intended to include all modifications within the meaning and scope, which are equivalent to the scope of claims.

### Explanation of Reference Numerals

10 SCHOTTKY JUNCTION FET

101 SILICON SUBSTRATE

102 ELEMENT ISOLATION REGION

103 GATE INSULATING FILM

104 GATE ELECTRODE

105 INSULATING FILM

106 RESIST PATTERN

107 SILICON NITRIDE FILM (INSULATING FILM)

108 METAL FILM

109, 110 SOURCE/DRAIN

111 GATE

1-4. (canceled)

5. A method for manufacturing a Schottky junction FET, comprising:
a first step of forming a gate on an element region defined in a surface layer of a silicon substrate by an element isolation region, the gate having an upper surface composed of a metal film covered with an insulating film;
a second step of etching the silicon substrate by self-alignment by using the gate and the element isolation region as masks;
a third step of adhering an insulating film onto an entirety of the silicon substrate, and etching back the insulating film by anisotropic etching, so as to form the insulating film on a side surface of the gate; and
a fourth step of immersing the silicon substrate into a plating solution, and selectively forming a metal film which is to be a source/drain, only on an etching region of the silicon substrate by an electroless plating method.

6. The method for manufacturing the Schottky junction FET according to claim 5, wherein the metal film of the source/drain is made of one type of metal selected from a group of gold, platinum, silver, copper, palladium, nickel, cobalt and ruthenium, or an alloy obtained by combining two types or more of the metal selected from the group with one another, or an alloy containing at least one type of the metal selected from the group.

7. A Schottky junction FET comprising:
a gate composed of a metal film, the gate being formed on an element region defined in a surface layer of a silicon substrate by an element isolation region; and
a source/drain formed on an etching region of the silicon substrate etched by using the gate and the element isolation region as masks,
wherein the source/drain has a metal film selectively formed by an electroless plating method.

8. The Schottky junction FET according to claim 7, wherein the metal film of the source/drain is made of one type of metal selected from a group of gold, platinum, silver, copper, palladium, nickel, cobalt and ruthenium, or an alloy obtained by combining two types or more of the metal selected from the group with one another, or an alloy containing at least one type of the metal selected from the group.
